(19) United States
(12) Patent Application Publication
(10) Pub. No.: US 2025/0191959 A1
(43) Pub. Date: Jun. 12, 2025

(54) SEMICONDUCTOR DEVICES WITH BENT POLYIMIDE TAPE AND ASSOCIATED MANUFACTURING METHODS

(71) Applicant: Infineon Technologies AG, Neubiberg (DE)

(72) Inventor: Rainer Markus SCHALLER, Aichen (DE)

(21) Appl. No.: 18/967,006

(22) Filed: Dec. 3, 2024

(30) Foreign Application Priority Data
Dec. 8, 2023 (DE) 102023212432.7

(51) Int. Cl. H01L 21/683; H01L 23/00; H01L 23/31; H01L 23/498; H10N 59/00

(52) U.S. Cl. CPC H01L 21/6836; H01L 23/3107; H01L 23/49838; H10N 59/00; H01L 24/48; H01L 2224/48175; H01L 2924/3025

(57) ABSTRACT

A semiconductor device includes an electrically conductive carrier, a semiconductor chip arranged over a section of the carrier, and a dielectric material arranged between the carrier section and the semiconductor chip. The dielectric material galvanically isolates the carrier section and the semiconductor chip from one another. The dielectric material includes a polyimide tape, wherein an edge region of the polyimide tape is bent away from the carrier section.

### TECHNICAL FIELD

The present disclosure relates to semiconductor devices with bent polyimide tape and methods for manufacturing such semiconductor devices.

### BACKGROUND

In semiconductor devices, high electric voltage differences between individual device components may occur during operation. By way of example, increased electric potential differences may arise in a current sensor between a busbar and a sensor chip arranged thereabove. Depending on material properties and a relative arrangement of the device components, increased voltage differences may lead to enormously high electric field strengths in specific spatial regions of the device. Device components arranged there may be subject to wear as a result of the high electric field strengths, and in the worst case this wear may lead to failure of the device.

Manufacturers and developers of semiconductor devices constantly endeavor to improve their products. In this context, it may be of particular interest both to lengthen the lifetime of the devices and to ensure their continuously safe operation. Moreover, it may be of interest to provide efficient and cost-effective methods for manufacturing such semiconductor devices.

### SUMMARY

Various aspects relate to a semiconductor device. The semiconductor device includes an electrically conductive carrier, a semiconductor chip arranged over a section of the carrier, and a dielectric material arranged between the carrier section and the semiconductor chip. The dielectric material galvanically isolates the carrier section and the semiconductor chip from one another. The dielectric material includes a polyimide tape, wherein an edge region of the polyimide tape is bent away from the carrier section.

Various aspects relate to a method for manufacturing a semiconductor device. The method includes providing an electrically conductive carrier and arranging a dielectric material on a section of the carrier. Here, arranging the dielectric material includes forming a polyimide tape with an edge region bent away from the carrier section. The method further includes arranging a semiconductor chip over the dielectric material, wherein the dielectric material galvanically isolates the carrier section and the semiconductor chip from one another.

### BRIEF DESCRIPTION OF THE DRAWINGS

Devices and methods according to the disclosure are explained in greater detail below with reference to drawings. Identical reference signs here may denote identical or similar components. The features of the various examples illustrated may be combined with one another, provided that they are not mutually exclusive, and/or they may be selectively omitted if they are not described as absolutely necessary.

FIG. 1 schematically shows a lateral sectional view of a semiconductor device 100 according to the disclosure.

FIG. 2 shows a flow diagram of a method for manufacturing a semiconductor device according to the disclosure.

FIG. 3A shows a lateral sectional view of a semiconductor device according to the disclosure, and FIG. 3B is a plan view of a polyimide tape as may be included in the semiconductor device.

FIG. 4A shows a lateral sectional view of a semiconductor device according to the disclosure, and FIG. 4B is a plan view of a polyimide tape as may be included in the semiconductor device.

FIG. 5A shows a lateral sectional view of a semiconductor device according to the disclosure, and FIG. 5B shows a plan view of a portion of the semiconductor device.

FIG. 6 shows a lateral sectional view of a semiconductor device according to the disclosure.

### DETAILED DESCRIPTION

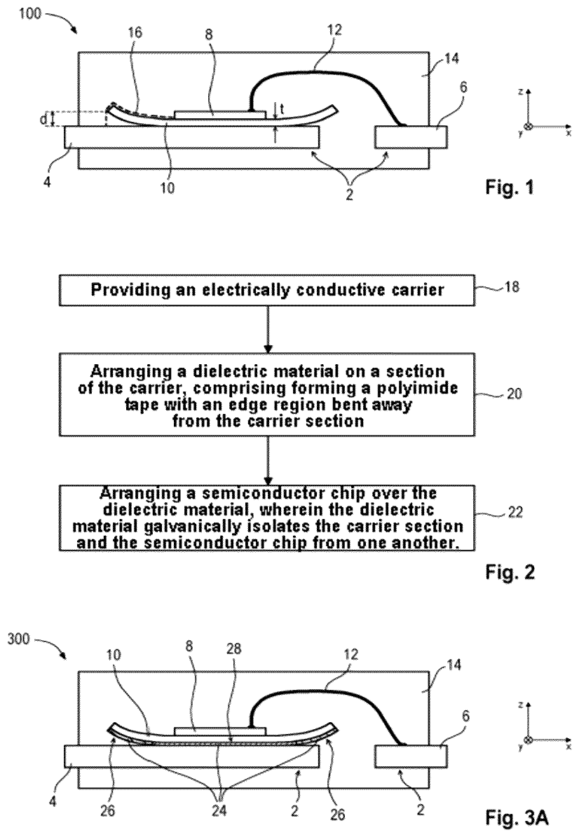

The semiconductor device 100 of FIG. 1 may include an electrically conductive carrier 2 with a first section 4 and a second section 6. A semiconductor chip 8 can be arranged above the first carrier section 4. The semiconductor device 100 may further include a dielectric material 10 arranged between the first carrier section 4 and the semiconductor chip 8. The dielectric material 10 can be configured to galvanically isolate the first carrier section 4 and the semiconductor chip 8 from one another. The dielectric material 10 may correspond to or contain a polyimide tape, wherein an edge region of the polyimide tape 10 is bent away from the first carrier section 4. The semiconductor chip 8 can optionally be electrically connected to the second section 6 of the carrier 2 via an electrical connection element 12. The components of the semiconductor device 100 may optionally be at least partially encapsulated in an encapsulation material 14.

In the example shown, the electrically conductive carrier 2 may be a leadframe. The leadframe 2 can be produced from a metal and/or a metal alloy, in particular from at least one of copper, copper alloys, nickel, iron-nickel, aluminum, aluminum alloys, steel, stainless steel or the like. During operation of the semiconductor device 100, the first carrier section 4 may be a current-carrying section. In particular, in the example shown, the first section 4 of the leadframe 2 can be a busbar which is configured to carry an electrical current which is intended to be detected or measured by the semiconductor chip 8. In the following, the terms “first carrier section”, “current-carrying section” and “busbar” can be used interchangeably. In particular, the busbar 4 can be formed or produced in one piece. The second section 6 of the leadframe 2 may have one or more leads (or lead fingers or pins or connecting conductors). Only one lead 6 can be seen in the lateral sectional view of FIG. 1 owing to the selected perspective. Any number of further leads 6 may be arranged, for example, behind the lead 6 shown.

In one example, the semiconductor chip 8 may be a sensor chip configured to sense a magnetic field generated by an electric current flowing through the busbar 4. Based on the sensed magnetic field (or the sensed magnetic flux density of the induced magnetic field), the magnitude of the electric current can be determined. In particular, the induced magnetic field can be measured (e.g., galvanically isolated) without physical contact between the sensor chip 8 and the busbar 4. In such a case, the sensor chip 8 (or more precisely at least one sensor element of the sensor chip 8) may at least partially overlap with the busbar 4 as viewed in the z-direction. The physical signals captured by the sensor chip 8 can be converted into electrical signals and forwarded via the electrical connecting element 12 and the lead 6 to further components (not shown) for further processing or evaluation. In the example shown, the electrical connection element 12 may correspond to or include a wire. Alternatively, or additionally, in further examples, the electrical connection element 12 may contain a clip, a band, or the like.

The sensor chip 8 may include one or more sensor elements (not shown). In one example, the sensor chip 8 may be a differential magnetic field sensor chip with two sensor elements. Generally, the sensor chip 8 and its sensor element(s) are not limited to a specific sensor technology. For example, a sensor element of the sensor chip 8 may be a Hall sensor element, a magnetoresistive sensor element, a vertical Hall sensor element or a fluxgate sensor element. An xMR magnetoresistive sensor element may be an AMR (anisotropic magneto-resistive) sensor element, a GMT (giant magneto-resistive) sensor element, or a TMR (tunnel magneto-resistive) sensor element. In one example, the sensor element or the sensor elements can be arranged on the upper side of the sensor chip 8 which faces away from the busbar 4. In further examples, the sensor element or the sensor elements can be arranged on an underside of the sensor chip 8 facing the busbar 4.

The polyimide tape 10 may galvanically isolate the sensor chip 8 and the busbar 4 from one another. An edge region of the polyimide tape 10 may be bent away from the busbar 4. This can result in a spacing of the edge region from the upper side of the busbar 4. For illustration purposes, FIG. 1 shows a distance d between the top side of the busbar 4 and the bottom side of the edge region of the polyimide tape 10. In particular, the entire edge of the polyimide tape 10 may be bent away from the busbar 4. In such a case, the entire edge of the polyimide tape 10 may then be spaced apart from the busbar 4. The polyimide tape 10 can thus in particular be of trough-shaped or shell-shaped form. As viewed in the z-direction, the base area of the polyimide tape 10 may have any suitable shape, for example round, oval, elliptical, square, rectangular, polygonal, or similar. In the example shown, the polyimide tape 10 may project at least partially beyond the right-hand edge of the busbar 4.

A thickness of the dielectric material or the polyimide tape 10 may be selected depending on the application of the semiconductor device 100. On the one hand, a thickness t of the polyimide tape 10 can be selected to be small enough such that the magnetic field generated by a measurement current at the location of the sensor element is strong enough for a measurement by the sensor chip 8. On the other hand, the thickness t of the polyimide tape 10 may be selected to be large enough such that an electrical isolation provided by the dielectric material between the busbar 4 and the sensor chip 8 is sufficiently large. For example, the thickness t of the polyimide tape 10 may be in a range from about 20 micrometers to about 200 micrometers. In specific, but by no means limiting examples, the polyimide tape 10 may have a thickness t of about 50 micrometers, or about 75 micrometers, or about 125 micrometers. The polyimide tape 10 may include or be made of any suitable polyimide, for example Kapton® and/or Upilex®.

The encapsulation material 14 may at least partially encapsulate one or more components of the semiconductor device 100. In particular, the busbar 4 and the semiconductor chip 8 may be at least partially embedded in the encapsulation material 14. Here, the encapsulation material 14 may be arranged between the busbar 4 and the bent edge region of the polyimide tape 10. The encapsulation material 14 may form a casing (or package) for the encapsulated device components to protect them from external influences, such as mechanical influences, chemical impurities, moisture, exposure to light, or the like. The semiconductor device 100 may also be referred to as a semiconductor package. The leads 6 can at least partly project from the encapsulation material 14, such that the semiconductor 8 can be electrically contacted from outside the encapsulation material 14. Similarly, the busbar 4 may at least partially protrude from the encapsulation material 14 to provide an input and an output for a measurement current.

The encapsulation material 14 may comprise at least one of an epoxy, a filled epoxy, an epoxy filled with glass fibers, an imide, a thermoplastic, a thermoset polymer, a polymer mixture, a laminate, or the like. Various techniques can be used for encapsulating the device components with the encapsulating material 14, for example at least one out of compression molding, injection molding, powder molding, liquid molding, map molding, lamination, or the like.

During operation of the semiconductor device 100, the electrical potential of the busbar 4 may differ from the electrical potential of the semiconductor chip 8. By way of example, the busbar 4 can be situated in a high-voltage range, while the semiconductor chip 8 (and the leads 6 electrically connected thereto) can be situated in a low-voltage range. A low-voltage range may be associated with or specified by an example range of values from about 0V to about 20V. In this context, example operating values of a low-voltage range may be about 3.3V or about 5V. A high-voltage range may be associated with or specified by an example range of values from about 50V to about 15000V. In this context, example operating values of a high-voltage range may be about 600 V, about 800 V, or about 1200V. In a non-limiting example, the electrical potential of the semiconductor chip 8 may be about 0V, while the electrical potential of the power rail 4 may be about 1000V.

Accordingly, large electric potential differences between the busbar 4 and the semiconductor chip 8 can occur during operation of the semiconductor device 100. These electrical potential differences can reach values of up to 1000 V or more. Galvanic isolation between the busbar 4 and the semiconductor chip 8 can be provided by the dielectric material 10 arranged therebetween. In this context, a capacitor (or plate capacitor) can be formed, wherein the busbar 4 and the semiconductor chip 8 can each form an electrode of the capacitor and the dielectric material 10 can form a fixed isolation between these electrodes.

Since the dielectric material 10 has an electrical isolating capability, high electric field strengths (or high inhomogeneous electric field peaks) may occur in certain spatial regions of the semiconductor device 100. The materials located in these regions may be exposed to high electrical voltages, which may be problematic in particular for materials with limited isolating capability. A high electrical load can lead to accelerated aging of the materials. In particular, an electrical “Treeing” may occur during the aging process of the semiconductor device 100. Generally, an electrical treeing may occur and propagate when a dielectric material is exposed to high and diverging electrical field voltages over a longer period of time. In this case, the electrical treeing may typically begin at corners and/or edges of the semiconductor chip and/or of a leadframe of the respective semiconductor device. Finally, it may result in the formation of one or more undesired breakdown paths between the semiconductor chip and the busbar, which may result in failure of the semiconductor device 100 in the worst case. FIG. 1 illustrates an example breakdown path 16 by a dashed line running between the semiconductor chip 8 and the busbar 4.

The bent edge region of the polyimide tape 10 may be configured to increase the length of a (potential) breakdown path between the semiconductor chip 8 and the busbar 4. In the semiconductor device 100, the breakdown path 16 would be shorter if the polyimide tape 10 were not bent but completely flat. As a result of the bent tape edge, it is thus possible to increase the electrical isolation by the polyimide tape 10 or a high-voltage strength. Moreover, the encapsulation material 14 arranged in the gap between the busbar 4 and the bent-up edge region of the polyimide tape 10 can additionally increase electrical isolation between the busbar 4 and the semiconductor chip 8. In addition to an extension of potential breakdown paths, electrical field strengths at the edge region of the polyimide tape 10 can be reduced by the bent shape of the polyimide tape 10. As a result, electrical breakdowns and/or electrical treeing can therefore be prevented or at least reduced by the polyimide tape 10 (and in particular by its bent shape).

In the example of FIG. 1, the use of the bent polyimide tape 10 for the case of a magnetic current sensor with a busbar 4 and a sensor chip 8 is described. Note that the concepts presented herein may also be applied to other semiconductor devices where high electrical potential differences may occur during operation. Examples are gate drivers, isolated drivers, digital isolators, auxiliary current components, or the like.

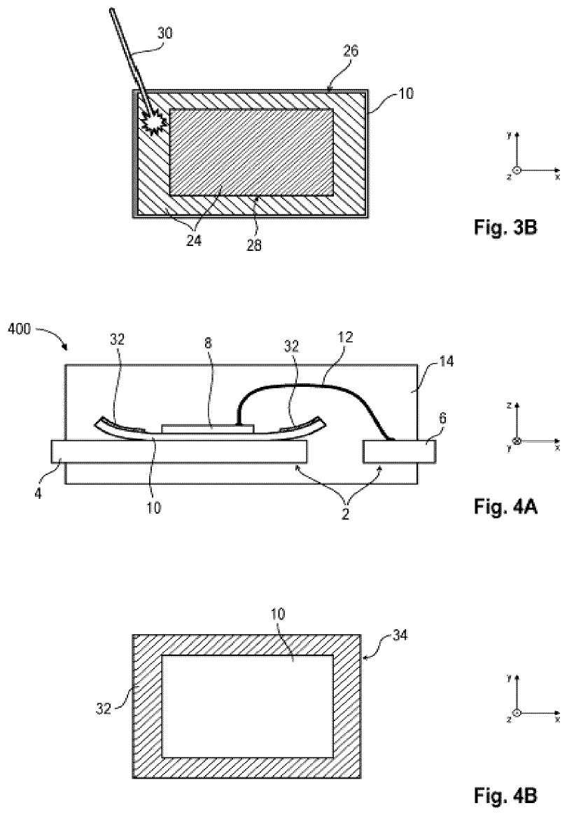

FIG. 2 shows a method for manufacturing a semiconductor device according to the disclosure. The method is illustrated in a general way in order to specify aspects of the disclosure qualitatively. The method can be used, for example, to manufacture the semiconductor device 100 of FIG. 1 and can therefore be read in connection with FIG. 1. The method may include further aspects which are described in conjunction with other figures described herein. Example extensions of the method are described in connection with FIGS. 3 to 5.

In a step 18, an electrically conductive carrier may be provided. In a step 20, a dielectric material may be arranged on a section of the carrier. In this case, the arrangement of the dielectric material may comprise forming a polyimide tape with an edge region bent away from the carrier section. In a step 24, a semiconductor chip may be arranged over the dielectric material. In this case, the dielectric material can galvanically isolate the carrier section and the semiconductor chip from one another.

The semiconductor device 300 of FIG. 3A may have some or all of the features of the semiconductor device 100 of FIG. 1. The semiconductor device 300 may include a die attach film (DAF) 24, which may be arranged on the bottom side of the polyimide tape 10. In this case, the die attach film 24 may have a lower adhesiveness in the bent edge region of the polyimide tape 10 than adjacent to the bent edge region.

In the plan view of FIG. 3B, an example configuration of a polyimide tape 10 with a die attach film 24 is shown, as may be included in the semiconductor device 300. The die attach film 24 may have an edge region 26 with a first adhesiveness and an inner region 28 with a second adhesiveness, wherein the first adhesiveness may be less than the second adhesiveness. In the example shown, the edge region 26 and the inner region 28 can have the shape of a rectangular frame or a rectangle. In further examples, however, the shapes of the two regions 26 and 28 may also be chosen differently.

The semiconductor device 300 can be manufactured, for example, with the method of FIG. 2, which in this context can be extended as follows. First, a die attach film 24 (or a dicing die attach film (D-DAF)) can be arranged (for example laminated) on a polyimide tape 10. The die attach film 24 may be, for example, a double-sided adhesive film, e.g., the polyimide tape 10 itself does not necessarily have to be adhesive. Subsequently, the adhesiveness of the die attach film 24, which initially has the same adhesion everywhere, can be reduced in a multiplicity of edge regions 26. In one example, the die attach film 24 may be processed with laser light 30 for this purpose, as indicated in FIG. 3B. Using a laser-induced thermal pulse, the material of the die attach film 24 can be at least partially cured in the frame-shaped edge regions 26, as a result of which the adhesiveness can be reduced.

In a further step, the polyimide tape 10 with the die attach film 24 arranged thereon can then be individualized (for example sawn) into a multiplicity of structures. A single such structure is shown in FIG. 3B and may subsequently be adhered to the first carrier section 4 with the die attach film 24. Then, the semiconductor chip 8 can be arranged on the polyimide tape 10 and electrically connected to the lead 6 via the electrical connection element 12. In a further step, the first carrier section 4 and the semiconductor chip 8 may be encapsulated with the encapsulation material 14. In this case, owing to the reduced adhesiveness in the edge region 26, the encapsulation material 14 can penetrate between the first carrier section 4 and the polyimide tape 10 and, in the process, bend the edge region of the polyimide tape 10 away from the first carrier section 4. In a molding process, the polyimide tape 10 can be bent upward solely by the flow of the molding material at its edge regions.

Optionally, one or more openings (not shown) may be formed in the first carrier section 4 prior to the encapsulation process. In one example, the first carrier section 4 may be structured by one or more cut-outs. During encapsulation, the encapsulation material 14 may then flow through the openings from below and thereby press the edge region of the polyimide tape 10 upward and away from the first carrier section 4. In the semiconductor device manufactured, the openings may thus be arranged below the bent edge region of the polyimide tape 10. The encapsulation material 14 may be arranged in the openings.

The semiconductor device 400 of FIG. 4A may have some or all of the features of semiconductor devices described above. The semiconductor device 400 may include a material layer 32, which may be arranged at the edge region of the polyimide tape 10. Here, the material layer 32 and the polyimide tape 10 may have different coefficients of thermal expansion.

In the plan view of FIG. 4B, an example configuration of a polyimide tape 10 with a material layer 32 is shown, as may be included in the semiconductor device 400. The material layer 32 may be arranged at an edge region 34 of the polyimide tape 10. In one example, the coefficient of thermal expansion of the material layer 32 may be greater than the coefficient of thermal expansion of the polyimide tape 10. In the case shown, the material layer 32 may have the example shape of a rectangular frame. The material layer 32 may include or be made from at least one of a polyimide, a polyimide with additives, a polyolefin, or the like. The material layer 32 can, for example, be an adhesive film. A thickness of the material layer 32 may be smaller than a thickness of the polyimide tape 10 and be in the range of individual micrometers.

The semiconductor device 400 can be manufactured, for example, with the method of FIG. 2, which in this context can be extended as follows. In one example, the material layer 32 may be selectively formed on the polyimide tape 10 at the edge region 34. Alternatively, the material layer 32 can first be applied to a larger region of the polyimide tape 10 and then suitably structured, for example using a photolithography process. After the application of the material layer 32, the edge region of the polyimide tape 10 can bend according to a bimetallic effect in the event of a change in temperature owing to the different coefficients of thermal expansion of the polyimide tape 10 and of the material layer 32. In one example, the material layer 32 may first be applied to the polyimide film 10 at an elevated temperature. Subsequently, the polyimide film 10 can bend during cooling owing to the different coefficients of thermal expansion.

In a further example, instead of a single polyimide tape 10, two tapes (for example polyimide tapes) with different coefficients of thermal expansion can be applied (for example laminated) to the first carrier section 4. The upper of the two tapes can be suitably structured, for example by a photolithography process. In one example, the tapes can first be laminated at an elevated temperature. Subsequently, the two tapes fastened to one another can bend according to a bimetallic effect on cooling owing to the different coefficients of thermal expansion.

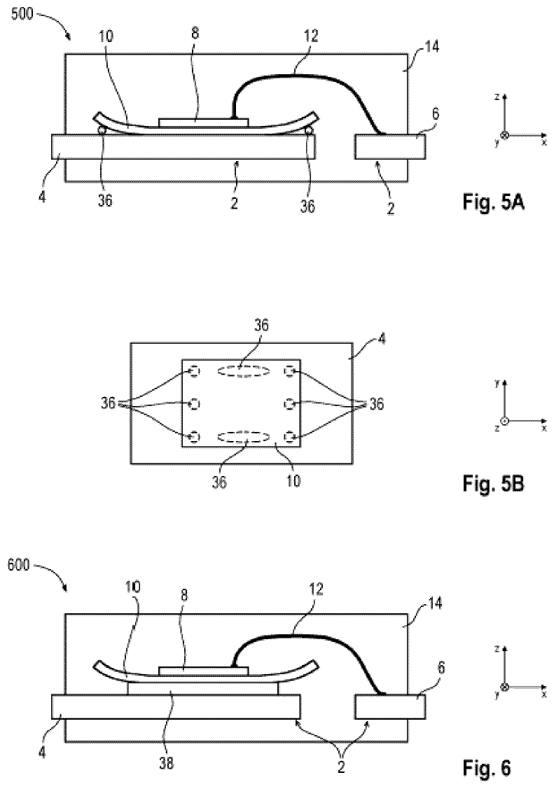

The semiconductor device 500 of FIG. 5A may have some or all of the features of semiconductor devices described above. The semiconductor device 500 may include one or more support structures 36 arranged between the first carrier section 4 and the bent edge region of the polyimide tape 10. The support structures 36 may be configured to bend the edge region of the polyimide tape 10 away from the first carrier section 4.

A possible example configuration of the support structures 36 is illustrated in the plan view of FIG. 5B. In practice, the components shown in FIG. 5B may be concealed and not visible by the encapsulation material 14. In the example plan view of FIG. 5B, the support structures 36 may have both circular and elongated shapes. The number and shapes of the support structures 36 can be chosen as desired as long as the edge region of the polyimide tape 10 is suitably bent away from the first carrier section 4. In a further case, for example, a single frame-shaped support structure may extend along the edge region of the polyimide tape 10. In yet another case, such a support structure may be interrupted at one or more points. The support structure 36 may be made of any suitable material, for example an (in particular epoxy resin-based) adhesive. For example, a thickness of the support structure 36 in the z-direction can be in a range of approximately 10 micrometers to approximately 20 micrometers.

The semiconductor device 500 can be manufactured, for example, with the method of FIG. 2, which in this context can be extended as follows. First, the support structure 36 can be arranged on the first carrier section 4. Subsequently, the polyimide tape 10 can be arranged on the support structure 36, wherein the edge region of the polyimide tape 10 is bent away from the first carrier section 4 by the support structure 36. In one example, arranging the support structure 36 may include applying an (in particular epoxy resin-based) adhesive to the first carrier section 4. The adhesive can be applied, for example, by an inkjet process and/or a dispensing process.

The sensor device 600 of FIG. 6 may have some or all of the features of semiconductor devices described above. The semiconductor device 600 may include a dielectric layer 38 arranged between the first carrier section 4 and the polyimide tape 10. In one example, the dielectric layer 38 may include or be fabricated from a polyimide (for example Kapton® and/or Upilex®). Viewed in the z-direction, a base area of the dielectric layer 38 may lie within a base area of the polyimide tape 10. The dielectric layer 38 may allow or facilitate the encapsulation material 14 to enter the space between the first carrier section 4 and the polyimide tape 10 during the encapsulation process and bend the polyimide tape 10 upward at its edges. In the example shown, the semiconductor device 600 may include a single dielectric layer 38. In further examples, a stack of a plurality of dielectric layers may be arranged between the first carrier section 4 and the polyimide tape 10. These layers may consist of the same material or of different materials.

The semiconductor devices according to the disclosure described herein may provide various technical effects. However, the following list is not to be understood as exhaustive. The person skilled in the art can identify further technical effects using the present description.

By using the bent polyimide tape, electrical breakdowns and/or electrical treeing can be prevented. As a result, longer lifetimes of the semiconductor devices can be achieved. The reliability of the semiconductor devices can be increased, such that, in particular, compliance with current and future standards (for example IEC standards) can be provided.

Owing to the low thickness of the polyimide tape (with a high electrical strength simultaneously present), the sensor chip arranged above the polyimide tape can provide a strong measurement signal.

The polyimide tape bent at the edge regions makes it possible to provide cost-effective electrical isolation between high-voltage and low-voltage regions in the semiconductor devices described herein. Compared to conventional solutions, both the costs of the materials used and those of the methods described herein may be lower.

The semiconductor devices described herein may be, for example, current sensors used for the operation of high-efficiency motor drives. Through such use, the energy consumption of such motors can be reduced while the power level of the motors can be kept constant or even increased. The reduced energy consumption of the engines can result, in particular, in reduced CO₂ emissions. Overall, the semiconductor devices described herein may therefore contribute to green technology and green energy solutions, e.g., to climate-friendly solutions with reduced energy consumption.

### ASPECTS

Semiconductor devices according to the disclosure and associated manufacturing methods are described below based on aspects.

Aspect 1 is a semiconductor device comprising: An electrically conductive carrier; a semiconductor chip arranged over a portion of the carrier; and a dielectric material arranged between the carrier section and the semiconductor chip, wherein the dielectric material galvanically isolates the carrier section and the semiconductor chip from one another, wherein the dielectric material comprises a polyimide tape, wherein an edge region of the polyimide tape is bent away from the carrier section.

Aspect 2 is a semiconductor device according to Aspect 1, wherein the carrier section is a current-carrying section during operation of the semiconductor device.

Aspect 3 is a semiconductor device according to Aspect 1 or 2, wherein the carrier section is in a high-voltage range during operation of the semiconductor device and the semiconductor chip is in a low-voltage range.

Aspect 4 is a semiconductor device according to any of the preceding Aspects, wherein: The carrier is a leadframe, the carrier section is a busbar, and the semiconductor chip is a sensor chip configured to sense a magnetic field generated by an electrical current flowing through the busbar.

Aspect 5 is a semiconductor device according to any of the preceding Aspects, wherein the bent edge region of the polyimide tape is configured to increase the length of a breakdown path between the semiconductor chip and the carrier section.

Aspect 6 is a semiconductor device according to any of the preceding Aspects, wherein the polyimide tape is tub-shaped.

Aspect 7 is a semiconductor device according to any of the preceding Aspects, wherein the polyimide tape has a thickness in a range of 20 micrometers to 200 micrometers.

Aspect 8 is a semiconductor device according to any of the preceding Aspects, further comprising: A die attach film arranged on the polyimide tape, wherein the die attach film has lower adhesiveness at the bent edge region of the polyimide tape than adjacent to the bent edge region.

Aspect 9 is a semiconductor device according to any of the preceding Aspects, further comprising: A material layer arranged at the edge region of the polyimide tape, wherein the material layer and the polyimide tape have different coefficients of thermal expansion.

Aspect 10 is a semiconductor device according to any of the preceding Aspects, further comprising: A support structure arranged between the carrier section and the bent edge region of the polyimide tape and configured to bend the edge region of the polyimide tape away from the carrier section.

Aspect 11 is a semiconductor device according to any of the preceding Aspects, wherein the dielectric material arranged between the carrier section and the semiconductor chip further comprises: A dielectric layer arranged between the carrier section and the polyimide tape, wherein a base area of the dielectric layer is within a base area of the polyimide tape.

Aspect 12 is a semiconductor device according to any of the preceding Aspects, further comprising: An encapsulation material at least partially encapsulating the semiconductor chip and the carrier section, wherein the encapsulation material is arranged between the carrier section and the edge region of the polyimide tape.

Aspect 13 is a semiconductor device according to Aspect 12, wherein the carrier section has at least one opening arranged below the bent edge region of the polyimide tape, wherein the encapsulation material is arranged in the at least one opening.

Aspect 14 is a method for manufacturing a semiconductor device, wherein the method comprises: Providing an electrically conductive carrier; arranging a dielectric material on a section of the carrier, wherein arranging the dielectric material comprises: Forming a polyimide tape with an edge region bent away from the carrier section; and arranging a semiconductor chip over the dielectric material, wherein the dielectric material galvanically isolates the carrier section and the semiconductor chip from one another.

Aspect 15 is a method according to Aspect 14, wherein forming the bent polyimide tape comprises: Arranging a die attach film on the polyimide tape, wherein the die attach film has a lower adhesiveness at the edge region of the polyimide tape than adjacent to the edge region; and encapsulating the carrier section and the semiconductor chip with an encapsulation material, wherein the encapsulation material penetrates between the carrier section and the edge region of the polyimide tape and thereby bends the edge region of the polyimide tape away from the carrier section.

Aspect 16 is a method according to Aspect 15, furthermore comprising: Processing the die attach film with laser light such that an adhesiveness of the die attach film at the edge region of the polyimide tape is reduced to produce the lower adhesiveness.

Aspect 17 is a method according to Aspect 15 or 16, furthermore comprising: Forming at least one opening in the carrier section, wherein the encapsulation material penetrates the at least one opening during encapsulating the carrier section and the semiconductor chip with the encapsulation material and, in the process, the encapsulation material bends the edge region of the polyimide tape away from the carrier section.

Aspect 18 is a method according to any one of Aspects 14 to 17, wherein forming the bent polyimide tape comprises: Forming a material layer at the edge region of the polyimide tape, wherein the material layer and the polyimide tape have different coefficients of thermal expansion, wherein the edge region of the polyimide tape is bent away from the carrier section in the event of a change in temperature owing to the different coefficients of thermal expansion. Forming the bent polyimide tape may include effecting or providing the change in temperate to cause the material layer and the polyimide tape to expand by differing amounts owing to the different coefficients of thermal expansion, thereby causing the edge region of the polyimide tape to bend away from the carrier section to produce a bent edge region.

Aspect 19 is a method according to Aspect 18, wherein forming the material layer comprises: Structuring the material layer by a photolithography process.

Aspect 20 is a method according to any one of Aspects 14 to 19, wherein forming the bent polyimide tape comprises: Arranging a support structure on the carrier section, and arranging the polyimide tape on the support structure, wherein the edge region of the polyimide tape is bent away from the carrier section by the support structure.

Aspect 21 is a method according to Aspect 20, wherein arranging the support structure comprises: Applying an epoxy resin-based adhesive to the carrier section by an inkjet process and/or a dispensing process.

Although specific implementations have been illustrated and described herein, it is obvious to a person of average skill in the art that a multiplicity of alternative and/or equivalent implementations may replace the specific implementations shown and described, without departing from the scope of the present disclosure. This application is intended to cover all adaptations or variations of the specific implementations discussed herein. Therefore, the intention is for this disclosure to be restricted only by the claims and the equivalents thereof.

1. A semiconductor device, comprising:
an electrically conductive carrier;
a semiconductor chip arranged over a carrier section of the electrically conductive carrier; and
a dielectric material arranged between the carrier section and the semiconductor chip, wherein the dielectric material galvanically isolates the carrier section and the semiconductor chip from one another,
wherein the dielectric material comprises a polyimide tape, and
wherein an edge region of the polyimide tape is bent away from the carrier section.

2. The semiconductor device of claim 1, wherein the carrier section is a current-carrying section during operation of the semiconductor device.

3. The semiconductor device as claimed in claim 1, wherein the carrier section is in a high-voltage range during operation of the semiconductor device, and the semiconductor chip is in a low-voltage region.

4. The sensor device as claimed in claim 1, wherein:
the electrically conductive carrier is a leadframe,
the carrier section is a busbar, and
the semiconductor chip is a sensor chip configured to sense a magnetic field generated by an electric current flowing through the busbar.

5. The semiconductor device according to claim 1, wherein the edge region of the polyimide tape is configured to increase a length of a breakdown path between the semiconductor chip and the carrier section.

6. The semiconductor device as claimed in claim 1, wherein the polyimide tape is trough-shaped.

7. The semiconductor device as claimed in claim 1, wherein the polyimide tape has a thickness in a range of 20 micrometers to 200 micrometers.

8. The semiconductor device as claimed in claim 1, further comprising:
a die attach film arranged on the polyimide tape, wherein the die attach film has a lower adhesiveness at the edge region of the polyimide tape than an adhesiveness in a region adjacent to the edge region.

9. The semiconductor device as claimed in claim 1, further comprising:
a material layer arranged at the edge region of the polyimide tape, wherein the material layer and the polyimide tape have different coefficients of thermal expansion.

10. The semiconductor device as claimed in claim 1, further comprising:
a support structure arranged between the carrier section and the bent edge region of the polyimide tape and which is configured to bend the edge region of the polyimide tape away from the carrier section.

11. The semiconductor device as claimed in claim 1, wherein the dielectric material arranged between the carrier section and the semiconductor chip further comprises:
a dielectric layer arranged between the carrier section and the polyimide tape, wherein a base area of the dielectric layer lies within a base area of the polyimide tape.

12. The semiconductor device as claimed in claim 1, further comprising:
an encapsulation material at least partially encapsulating the semiconductor chip and the carrier section, wherein the encapsulation material is arranged between the carrier section and the edge region of the polyimide tape.

13. The semiconductor device as claimed in claim 12, wherein the carrier section has at least one opening arranged below the edge region of the polyimide tape, and
wherein the encapsulation material is arranged in the at least one opening.

14. A method for manufacturing a semiconductor device, wherein the method comprises:
providing an electrically conductive carrier;
arranging a dielectric material on a carrier section of the electrically conductive carrier, wherein arranging the dielectric material comprises:
forming a polyimide tape with an edge region bent away from the carrier section; and
arranging a semiconductor chip over the dielectric material, wherein the dielectric material galvanically isolates the carrier section and the semiconductor chip from one another.

15. The method as claimed in claim 14, wherein forming the polyimide tape comprises:
arranging a die attach film on the polyimide tape, wherein the die attach film has a lower adhesiveness at the edge region of the polyimide tape than an adhesiveness in a region adjacent to the edge region; and
encapsulating the carrier section and the semiconductor chip with an encapsulation material, wherein the encapsulation material penetrates between the carrier section and the edge region of the polyimide tape such that the encapsulation material bends the edge region of the polyimide tape away from the carrier section.

16. The method as claimed in claim 15, further comprising:
processing the die attach film with laser light such that an adhesiveness of the die attach film at the edge region of the polyimide tape is reduced to produce the lower adhesiveness.

17. The method as claimed in claim 15, further comprising:
forming at least one opening in the carrier section, wherein the encapsulation material penetrates the at least one opening during encapsulating the carrier section and the semiconductor chip with the encapsulation material such that the encapsulation material bends the edge region of the polyimide tape away from the carrier section.

18. The method as claimed in claim 14, wherein forming the polyimide tape comprises:
forming a material layer at the edge region of the polyimide tape,
wherein the material layer and the polyimide tape have different coefficients of thermal expansion,
wherein, based on providing a change in temperature, the edge region of the polyimide tape is bent away from the carrier section owing to the different coefficients of thermal expansion.

19. The method as claimed in claim 18, wherein forming the material layer comprises:
structuring the material layer by a photolithography process.

20. The method as claimed in claim 14, wherein forming the polyimide tape comprises:
arranging a support structure on the carrier section, and
arranging the polyimide tape on the support structure, wherein the edge region of the polyimide tape is bent away from the carrier section by the support structure.

21. The method as claimed in claim 20, wherein arranging the support structure comprises:
applying an epoxy resin-based adhesive to the carrier section by an inkjet process or by a dispensing process.
